(19) United States
(12) Patent Application Publication
(10) Pub. No.: US 2015/0102464 A1
(43) Pub. Date: Apr. 16, 2015

(54) CAPACITOR WITH HOLE STRUCTURE AND MANUFACTURING METHOD THEREOF

(71) Applicant: Samsung Electro-Mechanics Co., Ltd., Suwon (KR)

(72) Inventors: Young Sik KANG, Daejeon (KR); Yeong Gyu LEE, Suwon (KR)

(73) Assignee: Samsung Electro-Mechanics Co., Ltd., Suwon (KR)

(21) Appl. No.: 14/051,894

(22) Filed: Oct. 11, 2013

(51) Int. Cl. H01L 49/02

(52) U.S. Cl. CPC H01L 28/90
USPC 257/535; 438/387

(57) ABSTRACT

Disclosed herein are a capacitor with a hole structure and a manufacturing method thereof. A capacitor with a hole structure includes: a substrate layer having a plurality of through-holes formed therein; a lower electrode layer including a first conductive layer having a low specific resistance and a second conductive layer having a specific resistance higher than that of the first conductive layer, the first conductive layer being formed on an inner wall of the through-hole and the second conducive layer being formed on the first conductive layer; a thin film dielectric layer formed on the lower electrode layer; and an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

### BACKGROUND OF THE INVENTION

1. Technical Field

The present invention relates to a capacitor with a hole structure and a manufacturing method thereof. More particularly, the present invention relates to a capacitor with a hole structure implementing a low equivalent series resistance (ESR) and a manufacturing method thereof.

2. Description of the Related Art

In accordance with expanding a market of a mobile communication device and a portable electronic device, a demand for a capacitor having a micro-size and a high capacitance value has recently increased. Therefore, a research into a thin film type multi-layered ceramic capacitor (MICC) capable of implementing miniaturization and obtaining the high capacitance value has actively been conducted. However, even in the case of the thin film type multi-layered ceramic capacitor, since it is configured of a multi-layered structure of several tens layers, there is limitation in decreasing a thickness thereof.

Recently, in order to solve the above-mentioned problem, a thin film type capacitor has actively been developed using a thin film electrode and a dielectric on a silicon substrate.

However, capacitance is highly increased, but there is limitation in using the electrode appropriate for characteristic of a thin film dielectric, thereby causing a high value of an internal equivalent series resistance (ESR) which is parasitic on the capacitor. The ESR is smaller, the capacitor has a better performance, and if a parasitic resistance exists, the parasitic resistance causes error in charging and discharging time and generates a leakage current, thereby serving to degrade system performance. Therefore, the high internal ESR is recently not appropriate for product performance requiring faster execution speed and low energy consumption such as a microprocessor unit (MPU), such that a practical use thereof cannot but be limited.

### RELATED ART DOCUMENT

### Patent Document

(Patent Document 1) International Patent Laid-Open Publication No. WO 01/50823 A1 (laid-open published on Jul. 12, 2001)
(Patent Document 2) US Patent Laid-Open Publication No. 2012/0080771 A1 (laid-open published on Apr. 5, 2012)

### SUMMARY OF THE INVENTION

An object of the present invention is to provide a capacitor with a hole structure capable of decreasing an internal ESR by attaching a conductive layer having a low resistance on upper and lower electrodes having a dielectric layer therebetween in a capacitor with a through-hole or a trench hole structure, and a manufacturing method thereof.

According to an exemplary embodiment of the present invention, there is provided a capacitor with a hole structure, including: a substrate layer having a plurality of through-holes formed therein; a lower electrode layer including a first conductive layer having a low specific resistance and a second conductive layer having a specific resistance higher than that of the first conductive layer, the first conductive layer being formed on an inner wall of the through-hole and the second conducive layer being formed on the first conductive layer; a thin film dielectric layer formed on the lower electrode layer; and an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

The capacitor with the hole structure may further include an adhesive seed layer forming an adhesive layer on a lower portion of the first conductive layer.

The capacitor with the hole structure may further include an insulating layer interposed between the lower electrode layer and the inner wall of the through-hole.

The first conductive layer and the fourth conductive layer may be made of the same material, and the second conductive layer and the third conductive layer may be made of the same material.

The dielectric layer may be made of one or more high dielectric materials selected from titanium oxide group, or a material having dopant added therein.

The first conductive layer and the fourth conductive layer may be made of one metal material of Cu, Ag, Au, Al, Ir, Ni, Co, Mo, and W, or a conductive oxide or a conductive nitride thereof, and the second conductive layer and the third conductive layer may be made of Ru material, or conductive polysilicon material having dopant added therein.

According to another exemplary embodiment of the present invention, there is provided a capacitor with a hole structure, including: a substrate layer having a plurality of trench-holes formed therein; a lower electrode layer including a first conductive layer having a low specific resistance and a second conductive layer having a specific resistance higher than that of the first conductive layer, the first conductive layer being formed on an inner wall of the trench-hole and the second conducive layer being formed on the first conductive layer; a thin film dielectric layer formed on the lower electrode layer; and an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

The capacitor with the hole structure may further include an insulating layer interposed between the lower electrode layer and the inner wall of the trench-hole.

The dielectric layer may be made of one or more high dielectric materials selected from titanium oxide group, or a material having dopant added therein.

The first conductive layer and the fourth conductive layer may be made of one metal material of Cu, Ag, Au, Al, Ir, Ni, Co, Mo, and W, or a conductive oxide or a conductive nitride thereof, and the second conductive layer and the third conductive layer may be made of Ru material, or conductive polysilicon material having dopant added therein.

According to another exemplary embodiment of the present invention, there is provided a manufacturing method of a capacitor with a hole structure, including: preparing a substrate having a plurality of through-holes formed therein; forming, on an inner wall of the through-hole, a lower electrode layer including a first conductive layer having a low specific resistance and a second conductive layer having a specific resistance higher than that of the first conductive layer, the first conductive layer being formed on the inner wall of the through-hole and the second conducive layer being formed on the first conductive layer; forming a thin film dielectric layer formed on the lower electrode layer; and forming, on the thin film dielectric layer, an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

The forming of the lower electrode layer may further include forming an adhesive seed layer on the inner wall of the through-hole, wherein the first conductive layer may be formed on the adhesive seed layer.

The preparing of the substrate may further include forming an insulating layer on the inner wall of the through-hole and a surface of the substrate, wherein the lower electrode layer may be formed on the insulating layer formed on the inner wall.

The dielectric layer may be made of one or more high dielectric materials selected from titanium oxide group, or a material having dopant added therein.

The lower electrode layer and the upper electrode layer may be formed by any one of ALD, CVD, PECVD, PVD, sputtering, and plating processes.

The first conductive layer and the fourth conductive layer may be made of one metal material of Cu, Ag, Au, Al, Ir, Ni, Co, Mo, and W, or a conductive oxide or a conductive nitride thereof, and the second conductive layer and the third conductive layer may be made of Ru material, or conductive polysilicon material having dopant added therein.

According to another exemplary embodiment of the present invention, there is provided a manufacturing method of a capacitor with a hole structure, including: preparing a substrate having a plurality of trench-holes formed therein; forming, on an inner wall of the trench-hole, a lower electrode layer including a first conductive layer having a low specific resistance and a second conductive layer having a specific resistance higher than that of the first conductive layer, the first conductive layer being formed on the inner wall of the trench-hole and the second conducive layer being formed on the first conductive layer; forming a thin film dielectric layer formed on the lower electrode layer; and forming, on the thin film dielectric layer, an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

The dielectric layer may be made of one or more high dielectric materials selected from titanium oxide group, or a material having dopant added therein.

The lower electrode layer and the upper electrode layer may be formed by any one of ALD, CVD, PECVD, PVD, sputtering, and plating processes.

The first conductive layer and the fourth conductive layer may be made of one metal material of Cu, Ag, Au, Al, Ir, Ni, Co, Mo, and W, or a conductive oxide or a conductive nitride thereof, and the second conductive layer and the third conductive layer may be made of Ru material, or conductive polysilicon material having dopant added therein.

### BRIEF DESCRIPTION OF THE DRAWINGS

FIG. 1 is a cross-sectional view schematically showing a capacitor with a hole structure according to an exemplary embodiment of the present invention;

FIGS. 2A to 2F are views schematically showing a manufacturing method of a capacitor with a hole structure according to an exemplary embodiment of the present invention;

FIG. 3 is a cross-sectional view schematically showing a capacitor with a hole structure according to another exemplary embodiment of the present invention;

FIG. 4 is a cross-sectional view schematically showing a capacitor with a hole structure according to another exemplary embodiment of the present invention;

FIG. 5 is a cross-sectional view schematically showing a capacitor with a hole structure according to another exemplary embodiment of the present invention; and

FIG. 6 is a cross-sectional view schematically showing a capacitor with a hole structure according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the description, the same reference numerals will be used to describe the same components of which a detailed description will be omitted in order to allow those skilled in the art to understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be examples for describing exemplary embodiments of the present invention. In the accompanying drawings, a shape, a size, a thickness, and the like, may be exaggerated in order to effectively describe technical characteristics.

First, a capacitor with a hole structure according to a first exemplary embodiment of the present invention will be described in detail with reference to the accompanying drawings. In the specification, the same reference numerals will be used in order to describe the same components throughout the accompanying drawings.

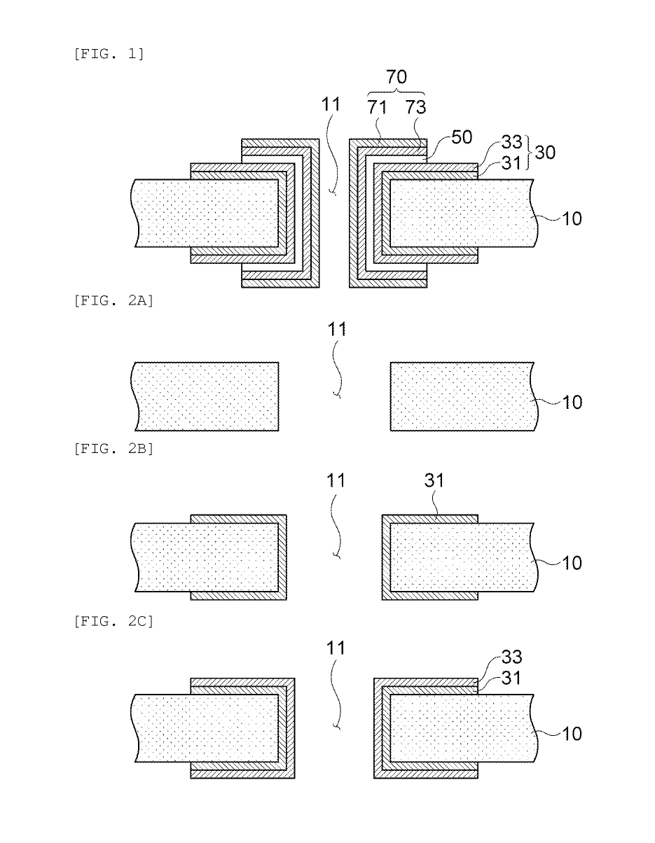

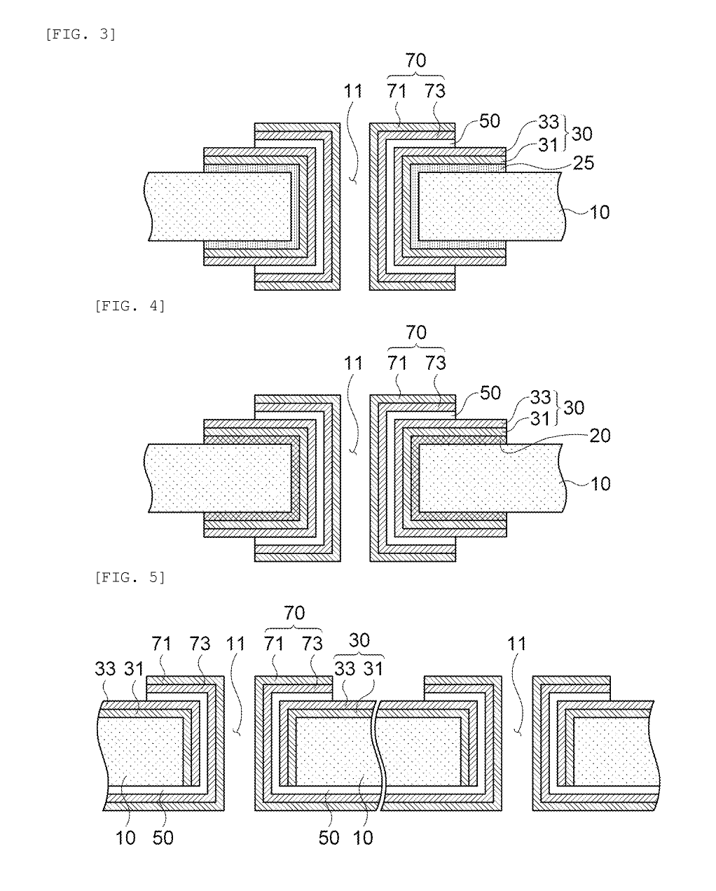

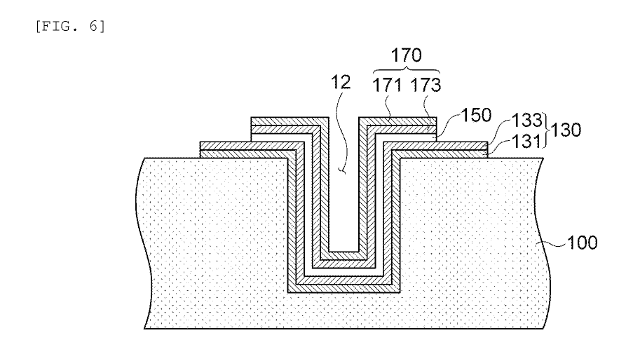

FIG. 1 is a cross-sectional view schematically showing a capacitor with a hole structure according to an exemplary embodiment of the present invention, FIG. 3 is a cross-sectional view schematically showing a capacitor with a hole structure according to another exemplary embodiment of the present invention, FIG. 4 is a cross-sectional view schematically showing a capacitor with a hole structure according to another exemplary embodiment of the present invention, and FIG. 5 is a cross-sectional view schematically showing a capacitor with a hole structure according to another exemplary embodiment of the present invention.

Referring to FIG. 1, the capacitor with the hole structure according to one example may be configured to include a substrate layer having a plurality of through-holes 11 formed therein, a lower electrode layer 30, a thin film dielectric layer 50, and an upper electrode layer 70. In addition, referring to FIG. 3, a capacitor with a hole structure according to another example may further include an adhesive seed layer 25. In addition, referring to FIG. 4, in another example, a capacitor with a hole structure may further include an insulating layer 20. The capacitor with the hole structure will be described based on FIG. 1 and the capacitor with the hole structure according to FIGS. 3 and 4 will be later described.

Specifically, the substrate layer 10 of the capacitor according to FIG. 1 includes the plurality of through-holes 11. A capacitor electrode is formed on the through-hole 11.

Next, the lower electrode layer 30 will be described in detail with reference to FIG. 1.

The lower electrode layer 30 of the capacitor according to FIG. 1 includes a first conductive layer 31 and a second conductive layer 33. In this case, the first conductive layer 31 is made of a conductive material having low specific resistance and the second conductive layer 33 is made of a conductive material having high specific resistance as compared to the first conductive layer 31.

The first conductive layer 31 of the lower electrode layer 30 is formed on an inner wall of the through-hole 11 formed in the substrate layer 10. In addition, the second conductive layer 33 is formed on the first conductive layer 31. Since the second conductive layer 33 contacting the thin film dielectric layer 50 has the high specific resistance, an internal equivalent series resistance (ESR) of the capacitor may be decreased by attaching the first conductive layer 31 having the low specific resistance to the second conductive layer 33. For example, referring to FIG. 3, in one example, the adhesive seed layer 25 may be added to a lower portion of the first conductive layer 31 in order to increase adhesion with the inner wall of the through-hole 11. In addition, referring to FIG. 4, in one example, the insulating layer 20 may be added between the first conductive layer 31 and the inner wall of the through-hole 11 of the substrate layer 10. In this case, although not shown, the adhesive seed layer may be added between the insulating layer 20 and the first conductive layer 31.

In this case, referring to FIG. 1, the lower electrode layer 30 may be formed on the inner wall of the through-hole 11 as well as across a surface of an upper surface and/or a lower surface of the substrate around the through-hole 11. For example, FIG. 1 shows the lower electrode layer 30 formed on the inner wall of the through-hole 11 and around the through-holeb11 of the upper surface and the lower surface of the substrate. Alternatively, referring to FIG. 5, the lower electrode layer 30 may be formed on the inner wall of the through-hole 11 and across any one surface of the upper surface and the lower surface of the substrate. For example, FIG. 5 shows the lower electrode layer 30 formed on the inner wall of the through-hole 11 and across the upper surface of the substrate 10.

In this case, the first conductive layer 31 may be made of one metal material of Cu, Ag, Au, Al, Ir, Ni, Co, Mo, and W, or a conductive oxide or a conductive nitride thereof. In addition, the second conductive layer 33 may be made of Ru material, or conductive polysilicon material having dopant added therein. For example, in this case, the dopant added in the conductive polysilicon may be made of a material including P, As, Sb or B element.

Next, the thin film dielectric layer 50 will be described in detail with reference to FIG. 1.

The thin film dielectric layer 50 of the capacitor according to FIG. 1 is formed on the lower electrode layer 30, specifically, on the second conductive layer 33. For example, the thin film dielectric layer 50 may be made of one or more high dielectric materials selected from titanium oxide group, or a material having the dopant added therein. For example, as the titanium oxide, TiO₂, ATO(Al—TiO₂), (Ba, Sr)TiO₃, SrTiO₃, BaTiO₃ and the like may be used. In addition, a compound having a bismuth layer shape such as SrBi₄Ti₄O₁₅ or the like may be used. Even though the thin film dielectric layer 50 is not made of the titanium oxide, for example, Pb(Zr,Ti)O₃ or the like may also be used.

For example, in this case, referring to FIG. 1, in the case in which the lower electrode layer 30 is formed on the inner wall of the through-hole 11 and across the surface of the upper surface and/or the lower surface of the substrate around the through-hole 11, the thin film dielectric layer 50 may be formed to expose at least part of the lower electrode layer 30 portion formed on the surface of the upper surface and/or the lower surface of the substrate around the through-hole 11. In this case, the upper electrode layer 70 may be formed in the same range as the thin film dielectric layer 50 or in a range of the thin film dielectric layer 50. Alternatively, referring to FIG. 5, in the case in which the lower electrode layer 30 is formed on the inner wall of the through-hole 11 and across any one surface of the upper surface and the lower surface of the substrate, the thin film dielectric layer 50 may be formed on the lower electrode layer 30 portion formed on the inner wall of the through-hole 11 and across the other of the upper surface and the lower surface of the substrate. In this case, the upper electrode layer 70 may be formed in the same range as the thin film dielectric layer 50 or in a range of the thin film dielectric layer 50.

Next, the upper electrode layer 70 will be described in detail with reference to FIG. 1.

The upper electrode layer 70 of the capacitor according to FIG. 1 includes a third conductive layer 73 and a fourth conductive layer 71. The fourth conductive layer 71 is made of a conductive material having a low specific resistance and the third conductive layer 73 is made of a conductive material having a high specific resistance as compared to the fourth conductive layer 71. In this case, the third conductive layer 73 of the upper electrode layer 70 is formed on the thin film dielectric layer 50 and the fourth conductive layer 71 is formed on the third conductive layer 73. Since the third conductive layer 73 contacting the thin film dielectric layer 50 has the high specific resistance, the internal equivalent series resistance (ESR) of the capacitor may be decreased by attaching the fourth conductive layer 71 having the low specific resistance to the third conductive layer 73. The first conductive layer 31 of the lower electrode layer 30 and the fourth conductive layer 71 of the upper electrode layer 70 are attached to the second conductive layer 33 and the third conductive layer 73 contacting the thin film dielectric layer 50, thereby making it possible to efficiently decrease the internal ESR between the lower and upper electrodes 30 and 70.

In this case, the fourth conductive layer 71 may be made of one metal material of Cu, Ag, Au, Al, Ir, Ni, Co, Mo, and W, or a conductive oxide or a conductive nitride thereof. In addition, the third conductive layer 73 may be made of a conductive polysilicon having Ru or dopant contained therein. For example, in this case, the dopant added in the conductive polysilicon may be made of a material including P, As, Sb or B element.

In addition, in one example, the first conductive layer 31 of the lower electrode layer 30 and the fourth conductive layer 71 of the upper electrode layer 70 may be made of the same material. Moreover, the second conductive layer 33 of the lower electrode layer 30 and the third conductive layer 73 of the upper electrode layer 70 may be made of the same material.

Another example will be described with reference to FIG. 3.

The capacitor with the hole structure according to one example may further include the adhesive seed layer 25 forming an adhesive layer on the lower portion of the first conductive layer 31. In this case, the adhesive seed layer 25 may be made of one metal material selected from Ti, Cr, Mo, Ru, Cu, Au, and Ni.

In addition, describing another example with reference to FIG. 4, the capacitor with the hole structure may further include the insulating layer 20. The insulating layer 20 may be interposed between the lower electrode layer 30 and the inner wall of the through-hole 11, for example, between the first conductive layer 31 and the inner wall of the through-hole 11. The insulating layer 20 may use an inorganic protection layer (SiNx, SiOx, TiOx, TaOx, SiON, AlOx), an organic protection layer (or an organic insulating layer) (polyimide resin, epoxy resin and the like) as the material thereof. In this case, although not shown, the adhesive seed layer (see reference number 25 of FIG. 3) for improving the adhesion between the insulating layer 20 and the first conductive layer 31 may be further added between the insulating layer 20 and the first conductive layer 31.

Next, a capacitor with a hole structure according to a second exemplary embodiment of the present invention will be described in detail with reference to the accompanying drawings. Here, the capacitor with the hole structure according to the first exemplary embodiment of the present invention described above and FIGS. 3 to 5 may be referred. Therefore, overlapped descriptions will be omitted.

FIG. 6 is a cross-sectional view schematically showing a capacitor with a hole structure according to another exemplary embodiment of the present invention.

Referring to FIG. 6, the capacitor with the hole structure according to one example may be configured to include a substrate layer 100 having a plurality of trench-holes 12 formed therein, a lower electrode layer 130, a thin film dielectric layer 150, and an upper electrode layer 170. In addition, although not shown, referring to FIG. 3, in one example, the capacitor may further include an adhesive seed layer 25. In addition, although not shown, referring to FIG. 4, in another example, the capacitor may further include an insulating layer 20.

The respective configurations of the lower electrode layer 130, the thin film dielectric layer 150, and the upper electrode layer 170 of the capacitor with the hole structure according to FIG. 6 have those similar to the capacitor with the hole structure according to the first exemplary embodiment, except that the lower electrode layer 130, the thin film dielectric layer 150, and the upper electrode layer 170 are formed on the trench-hole 12 of the substrate layer 100.

In this case, the substrate layer 100 of the capacitor according to FIG. 6 includes the plurality of trench-holes 12. The trench-hole 12 may be formed by an etching process, or by laminating substrates including the through-hole 11. Although not shown, describing a case in which the trench-hole 12 is formed using a laminated substrate, the trench-hole 12 may be formed by laminating upper substrates having the plurality of through-holes formed therein on a base substrate. In this case, although not shown, a conductive pattern layer is formed between the base substrate and the upper substrate having the through-hole formed therein, and the lower electrode layer 130 formed on a lower surface in the trench-hole 12 formed by the through-hole may contact the conductive pattern layer.

Next, the lower electrode layer 130 will be described in detail with reference to FIG. 6.

The lower electrode layer 130 of the capacitor with the hole structure according to FIG. 6 includes a first conductive layer 131 and a second conductive layer 133. The first conductive layer 131 is made of a conductive material having a low specific resistance as compared to the second conductive layer 133. In this case, the first conductive layer 131 of the lower electrode layer 130 is formed on an inner wall, for example, a side wall and a bottom of the trench-hole 12 formed on the substrate layer 100 and the second conductive layer 133 is formed on the first conductive layer 131. Since the second conductive layer 133 contacting the thin film dielectric layer 150 has the high specific resistance, an internal equivalent series resistance (ESR) of the capacitor may be decreased by attaching the first conductive layer 131 having the low specific resistance to the second conductive layer 133.

For example, although not shown directly, referring to FIG. 3, the adhesive seed layer 25 may be added to a lower portion of the first conductive layer 131 in order to increase adhesion with the inner wall of the trench-hole 12. In addition, although not shown directly, referring to FIG. 4, in one example, the insulating layer 20 may be added between the first conductive layer 131 and the inner wall of the trench-hole 12 of the substrate. In addition, although not shown, the adhesive seed layer may be added between the insulating layer 20 and the first conductive layer 131.

In this case, the first conductive layer 131 may be made of one metal material of Cu, Ag, Au, Al, Ir, Ni, Co, Mo, and W, or a conductive oxide or a conductive nitride thereof. In addition, the second conductive layer 133 may be made of Ru material, or conductive polysilicon material having dopant added therein. For example, in this case, the dopant added in the conductive polysilicon may be made of a material including P, As, Sb or B element.

Next, the thin film dielectric layer 150 will be described in detail with reference to FIG. 6. The thin film dielectric layer 150 of the capacitor according to FIG. 6 is formed on the second conductive layer 133 of the lower electrode layer 130. In this case, according to one example, the thin film dielectric layer 150 may be made of one or more high dielectric materials selected from titanium oxide group, or a material having the dopant added therein. For example, as the titanium oxide, TiO₂, ATO(Al—TiO₂), (Ba, Sr)TiO₃, SrTiO₃, BaTiO₃ and the like may be used. In addition, a compound having a bismuth layer shape such as SrBi₄Ti₄O₁₅ or the like may be used. Even though the thin film dielectric layer 50 is not made of the titanium oxide, for example, Pb(Zr,Ti)O₃ or the like may also be used.

Next, the upper electrode layer 170 will be described in detail with reference to FIG. 6.

The upper electrode layer 170 of the capacitor according to FIG. 6 includes a third conductive layer 173 and a fourth conductive layer 171. The fourth conductive layer 171 is made of a conductive material having a low specific resistance as compared to the third conductive layer 173. In this case, the third conductive layer 173 of the upper electrode layer 170 is formed on the thin film dielectric layer 150 and the fourth conductive layer 171 is formed on the third conductive layer 173. The first conductive layer 131 of the lower electrode layer 130 and the fourth conductive layer 171 of the upper electrode layer 170 are attached to the second conductive layer 133 and the third conductive layer 173 contacting the thin film dielectric layer 150, thereby making it possible to efficiently decrease the internal ESR between the lower and upper electrodes 130 and 170.

In this case, the fourth conductive layer 171 may be made of one metal material of Cu, Ag, Au, Al, Ir, Ni, Co, Mo, and W, or a conductive oxide or a conductive nitride thereof. In addition, the third conductive layer 173 may be made of Ru material, or conductive polysilicon material having dopant added therein. For example, in this case, the dopant added in the conductive polysilicon may be made of a material including P, As, Sb or B element.

In addition, in one example, the first conductive layer 131 of the lower electrode layer 130 and the fourth conductive layer 171 of the upper electrode layer 170 may be made of the same material, and the second conductive layer 133 of the lower electrode layer 130 and the third conductive layer 173 of the upper electrode layer 170 may be made of the same material.

Next, a manufacturing method of a capacitor with a hole structure according to a third exemplary embodiment of the present invention will be described in detail with reference to the accompanying drawings. Here, the capacitor with the hole structure according to the first exemplary embodiment of the present invention described above and FIGS. 1, 3, 4 and 5 may be referred. Therefore, overlapped descriptions will be omitted.

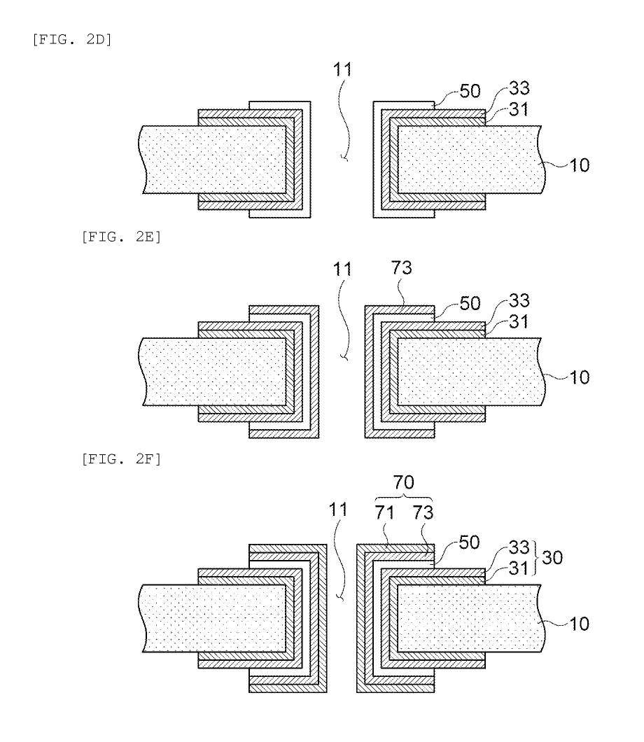

FIGS. 2A to 2F are views schematically showing a manufacturing method of a capacitor with a hole structure according to an exemplary embodiment of the present invention.

Referring to FIGS. 2A to 2F, the manufacturing method of the capacitor with the hole structure according to an exemplary embodiment of the present invention may include preparing a substrate 10 of FIG. 2A, forming a lower electrode layer 30 of FIGS. 2B and 2C, forming a dielectric layer 50 of FIG. 2D, and forming an upper electrode layer 70 of FIGS. 2E and 2F.

First, referring to FIG. 2A, in the preparing of the substrate 10, the substrate 10 having a plurality of through-holes 11 formed therein is prepared.

In this case, although not shown directly, referring to FIG. 4, the preparing of the substrate 10 may further include forming an insulating layer 20 on an inner wall of the through-hole 11 and a surface of the substrate 10. The insulating layer 20 may be made of SiO2 material, for example, or may use an inorganic protection layer (SiNx, SiOx, TiOx, TaOx, SiON, AlOx), an organic protection layer (or an organic insulating layer) (polyimide resin, epoxy resin and the like) as the material thereof.

Next, the forming of the lower electrode layer 30 will be described in detail with reference to FIGS. 2B and 2C. In this case, the lower electrode layer 30 includes a first conductive layer 31 having a low specific resistance and a second conductive layer 33 having a specific resistance higher than that of the first conductive layer 31.

Referring to FIG. 2B, the first conductive layer 31 of the lower electrode layer 30 is formed on the inner wall of the through-hole 11 formed in the substrate layer 10. Next, referring to FIG. 2C, the second conductive layer 33 of the lower electrode layer 30 is formed on the first conductive layer 31. Since the second conductive layer 33 contacting the thin film dielectric layer 50 formed in the subsequent forming of the thin film dielectric layer 50 of FIG. 2D has the high specific resistance, internal ESR of the capacitor may be decreased by first forming the first conducive layer 31 having the low specific resistance as shown in FIG. 2B and attaching the second conductive layer 33 on the first conductive layer 31 as shown in FIG. 2C.

In this case, in one example, in the forming of the lower electrode layer 30 of FIGS. 2B and 2C, the first conductive layer 31 and the second conductive layer 33 may be formed by any one of atomic layer deposition (ALD), plasma enhanced atomic layer deposition (PEALD), chemical vapor deposition (CVD), plasma enhanced chemical vapor deposition (PECVD), metalorganic chemical vapor deposition (MOCVD), physical vapor deposition (PVD), sputtering, and plating processes. For example, the first conductive layer 31 and the second conductive layer 33 may be formed by the atomic layer deposition (ALD) process, the sputtering process, or the plating process.

In addition, one example, the first conductive layer 31 may be made of one metal material of Cu, Ag, Au, Al, Ir, Ni, Co, Mo, and W, or a conductive oxide or a conductive nitride thereof. In addition, the second conductive layer 33 may be made of Ru material, or conductive polysilicon material having dopant added therein. For example, in this case, the dopant added in the conductive polysilicon may be made of a material including P, As, Sb or B element.

In addition, although not shown in FIG. 2B, referring to FIG. 3, in one example, in the forming of the first conductive layer 31, the adhesive seed layer 25 may be first formed in order to increase the adhesion between the inner wall of the through-hole 11 of the substrate layer 10 and the first conductive layer 31 before forming the first conductive layer 31. In this case, the adhesive seed layer 25 may be made of one metal material selected from Ti, Cr, Mo, Ru, Cu, Au, and Ni. In addition, although not shown in FIG. 2B, referring to FIG. 4, in one example, the insulating layer 20 may be additionally formed on the inner wall of the through-hole 11 of the substrate layer 10 on which the first conductive layer 31 is formed. That is, the lower electrode layer 30, especially the first conductive layer 31 is formed on the insulating layer 20 formed on the inner wall. In addition, although not shown, the adhesive seed layer may be added between the insulating layer 20 and the first conductive layer 31.

Next, the forming of the thin film dielectric layer 50 will be described in detail with reference to FIG. 2D. Referring to FIG. 2D, the thin film dielectric layer 50 is formed on the second conductive layer 33 of the lower electrode layer 30. In this case, the thin film dielectric layer 50 may be formed by any one of the ALD, PEALD, CVD, MOCVD, PECVD, PVD, and sputtering processes.

In addition, according to one example, the thin film dielectric layer 50 may be made of one or more high dielectric materials selected from titanium oxide group, or a material having the dopant added therein. For example, as the titanium oxide, TiO₂, ATO(Al—TiO₂), (Ba, Sr)TiO₃, SrTiO₃, BaTiO₃ and the like may be used. In addition, a compound having a bismuth layer shape such as SrBi₄Ti₄O₁₅ or the like may be used. Even though the thin film dielectric layer 50 is not made of the titanium oxide, for example, Pb(Zr,Ti)O₃ or the like may also be used.

Next, the forming of the upper electrode layer 70 will be described in detail with reference to FIGS. 2E and 2F. The upper electrode layer 70 formed in FIGS. 2E and 2F includes a third conductive layer 73 and a fourth conductive layer 71. In this case, the fourth conductive layer 71 is made of a conductive material having a low specific resistance as compared to the third conductive layer 73.

Referring to FIG. 2E, the third conductive layer 73 of the upper electrode layer 70 is formed on the thin film dielectric layer 50. In addition, referring to FIG. 2F, the fourth conductive layer 71 of the upper electrode layer 70 is formed on the third conductive layer 73. Therefore, the first conductive layer 31 of the lower electrode layer 30 and the fourth conductive layer 71 of the upper electrode layer 70 are attached to the second conductive layer 33 and the third conductive layer 73 contacting the thin film dielectric layer 50, thereby making it possible to efficiently decrease the internal ESR between the lower and upper electrodes 30 and 70.

In this case, in one example, the third conductive layer 73 and the fourth conductive layer 71 in the forming of the fourth conductive 71 of FIG. 2E and the forming of the third conductive layer 73 of FIG. 2F may be formed by any one of the ALD, PEALD, CVD, PECVD, MOCVD, PVD, sputtering, and plating processes. For example, the third conductive layer 73 and the fourth conductive layer 71 may be formed by the ALD process, the sputtering process, or the plating process. For example, the third conductive layer 73 may be formed by the ALD process or the sputtering process, and the fourth conductive layer 71 may be formed by the plating process.

In addition, one example, the first conductive layer 71 may be made of one metal material of Cu, Ag, Au, Al, Ir, Ni, Co, Mo, and W, or a conductive oxide or a conductive nitride thereof. In addition, the third conductive layer 73 may be made of Ru material, or conductive polysilicon material having dopant added therein. For example, in this case, the dopant added in the conductive polysilicon may be made of a material including P, As, Sb or B element.

In another example, the first conductive layer 31 of FIG. 2B and the fourth conductive layer 71 of FIG. 2F may be made of the same material. Moreover, the second conductive layer 33 of FIG. 2C and the third conductive layer 73 of FIG. 2E may be made of the same material.

Next, a manufacturing method of a capacitor with a hole structure according to a fourth exemplary embodiment of the present invention will be described in detail with reference to the accompanying drawings. Here, the capacitor with the hole structure according to the second exemplary embodiment of the present invention described above, the manufacturing method of the capacitor with the hole structure according to the third exemplary embodiment of the present invention described above, FIGS. 2A to 2F, and FIG. 6 may be referred. Therefore, overlapped descriptions will be omitted.

Although not shown directly, referring to FIGS. 2A to 2F and FIG. 6, the manufacturing method of the capacitor with the hole structure according to one example may include preparing a substrate 100, forming a lower electrode layer 130, forming a dielectric layer 150, and forming an upper electrode layer 170. In this case, the forming of the lower electrode layer 130, the forming of the dielectric layer 150, and the forming of the upper electrode layer 170, respectively, of the manufacturing method of the capacitor with hole structure according to the present embodiment have those similar to the manufacturing method of the capacitor with the hole structure according to FIGS. 2B to 2F, except that the lower electrode layer 130, the thin film dielectric layer 150, and the upper electrode layer 170 are formed on the trench-hole 12 of the substrate layer 100.

First, although not shown directly, referring to FIGS. 2A and 6, in the preparing of the substrate 100, the substrate 100 having a plurality of trench-holes 12 formed therein is prepared. The trench-hole 12 may be formed by an etching process, or by laminating substrates including the through-hole. Although not shown, describing a case in which the trench-hole 12 is formed using a laminated substrate, the trench-hole 12 may be formed by laminating upper substrates having the plurality of through-holes formed therein on a base substrate. In this case, although not shown, a conductive pattern layer is formed between the base substrate and the upper substrate having the through-hole formed therein, and the lower electrode layer 130 formed on a lower surface in the trench-hole 12 formed by the through-hole may contact the conductive pattern layer.

In addition, although not shown directly, referring to FIG. 4, the preparing of the substrate 100 may further include forming an insulating layer 20 on an inner wall of the trench-hole 12 and a surface of the substrate 10.

Next, although not shown directly, the forming of the lower electrode layer 130 will be described in detail with reference to FIGS. 2B, 2C, and 6. In this case, the lower electrode layer 130 includes a first conductive layer 131 having a low specific resistance and a second conductive layer 133 having a specific resistance higher than that of the first conductive layer 131. The first conductive layer 131 of the lower electrode layer 130 is formed on an inner wall of the trench-hole 12 formed in the substrate layer 100. Next, the second conductive layer 133 of the lower electrode layer 130 is formed on the first conductive layer 131. Since the second conductive layer 133 contacting the thin film dielectric layer 150 formed in the subsequent forming of thin film dielectric layer 150 has the high specific resistance, an internal ESR of the capacitor may be decreased by first forming the first conductive layer 131 having the low specific resistance and attaching the second conductive layer 133 on the first conductive layer 131.

In this case, in one example, in the forming of the lower electrode layer 130, the first conductive layer 131 and the second conductive layer 133 may be formed by any one of the ALD, PEALD, CVD, PECVD, MOCVD, PVD, sputtering, and plating processes. For example, the first conductive layer 131 and the second conductive layer 133 may be formed by the ALD process, the sputtering process, or the plating process.

In addition, one example, the first conductive layer 131 may be made of one metal material of Cu, Ag, Au, Al, Ir, Ni, Co, Mo, and W, or a conductive oxide or a conductive nitride thereof. In addition, the second conductive layer 133 may be made of Ru material, or conductive polysilicon material having dopant added therein.

In addition, although not shown directly, referring to FIGS. 3 and 6 in combination, in one example, in the forming of the first conductive layer 131, the adhesive seed layer 25 may be first formed in order to increase the adhesion between the inner wall of the trench-hole 12 of the substrate layer 100 and the first conductive layer 131 before forming the first conductive layer 131. In addition, although not shown, in one example, the adhesive seed layer 25 may be formed on the insulating layer formed on the inner wall of the trench-hole 12 of the substrate layer 100. In addition, although not shown directly, referring to the insulating layer 20 described in FIG. 4, in one example, in the forming of the first conductive layer 131, the first conductive layer 131 may be formed on the insulating layer formed on the inner wall of the trench-hole 12.

Next, although not shown directly, describing the forming of the thin film dielectric layer 150 with reference to FIGS. 2D and 6 in combination, the thin film dielectric layer 150 is formed on the second conductive layer 133 of the lower electrode layer 130. In this case, the thin film dielectric layer 150 may be formed by any one of the ALD, PEALD, CVD, MOCVD, PECVD, PVD, and sputtering processes.

In addition, according to one example, the thin film dielectric layer 150 may be made of one or more high dielectric materials selected from titanium oxide group, or a material having the dopant added therein. For example, as the titanium oxide, TiO₂, ATO(Al—TiO₂), (Ba, Sr)TiO₃, SrTiO₃, BaTiO₃ and the like may be used. In addition, a compound having a bismuth layer shape such as SrBi₄Ti₄O₁₅ or the like may be used. Even though the thin film dielectric layer 50 is not made of the titanium oxide, for example, Pb(Zr,Ti)O₃ or the like may also be used.

Next, the forming of the upper electrode layer 170 will be described in detail with reference to FIGS. 2E, 2F, and 6 in combination. In this case, the formed upper electrode layer 170 includes a third conductive layer 173 and a fourth conductive layer 171. The fourth conductive layer 171 is formed of a conductive material having a low specific resistance as compared to the third conductive layer 173. First, the third conductive layer 173 of the upper electrode layer 170 is formed on the thin film dielectric layer 150 and the fourth conductive layer 171 of the upper electrode layer 170 is formed on the third conductive layer 173. Therefore, the first conductive layer 131 of the lower electrode layer 130 and the fourth conductive layer 171 of the upper electrode layer 170 are attached to the second conductive layer 133 and the third conductive layer 173 contacting the thin film dielectric layer 150, thereby making it possible to efficiently decrease the internal ESR between the lower and upper electrodes 130 and 170.

In this case, in one example, the third conductive layer 173 and the fourth conducive layer 171 of the upper electrode layer 170 may be formed by any one of the ALD, PEALD, CVD, PECVD, MOCVD, PVD, sputtering, and plating processes. For example, the third conductive layer 173 and the fourth conductive layer 171 may be formed by the ALD process, the sputtering process, or the plating process.

In addition, one example, the first conductive layer 171 may be made of one metal material of Cu, Ag, Au, Al, Ir, Ni, Co, Mo, and W, or a conductive oxide or a conductive nitride thereof. In addition, the third conductive layer 173 may be made of Ru material, or conductive polysilicon material having dopant added therein. For example, in this case, the dopant added in the conductive polysilicon may be made of a material including P, As, Sb or B element.

In another example, the first conductive layer 131 of the lower electrode layer 130 and the fourth conductive layer 171 of the upper electrode layer 170 may be made of the same material. Moreover, the second conductive layer 133 and the third conductive layer 173 may be made of the same material.

According to the exemplary embodiment of the present invention, the conductive layer having a low resistance is attached on the upper and lower electrodes having a dielectric layer therebetween in the capacitor with the through-hole or the trench hole structure, thereby making it possible to decrease the internal ESR.

As a result, the high capacitance and the low internal ESR may be simultaneously satisfied.

It is obvious that various effects directly not stated according to various exemplary embodiments of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to the claims and includes various modifications, alterations, and equivalences made by those skilled in the art.

What is claimed is:

1. A capacitor with a hole structure, comprising:
a substrate layer having a plurality of through-holes formed therein;
a lower electrode layer including a first conductive layer having a low specific resistance and a second conductive layer having a specific resistance higher than that of the first conductive layer, the first conductive layer being formed on an inner wall of the through-hole and the second conducive layer being formed on the first conductive layer;
a thin film dielectric layer formed on the lower electrode layer; and
an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

2. The capacitor with the hole structure according to claim 1, further comprising an adhesive seed layer forming an adhesive layer on a lower portion of the first conductive layer.

3. The capacitor with the hole structure according to claim 1, further comprising an insulating layer interposed between the lower electrode layer and the inner wall of the through-hole.

4. The capacitor with the hole structure according to claim 1, wherein the first conductive layer and the fourth conductive layer are made of the same material, and
the second conductive layer and the third conductive layer are made of the same material.

5. The capacitor with the hole structure according to claim 1, wherein the dielectric layer is made of one or more high dielectric materials selected from titanium oxide group, or a material having dopant added therein.

6. The capacitor with the hole structure according to claim 5, wherein the first conductive layer and the fourth conductive layer are made of one metal material of Cu, Ag, Au, Al, Ir, Ni, Co, Mo, and W, or a conductive oxide or a conductive nitride thereof, and
the second conductive layer and the third conductive layer are made of Ru material, or conductive polysilicon material having dopant added therein.

7. A capacitor with a hole structure, comprising:
a substrate layer having a plurality of trench-holes formed therein;
a lower electrode layer including a first conductive layer having a low specific resistance and a second conductive layer having a specific resistance higher than that of the first conductive layer, the first conductive layer being formed on an inner wall of the trench-hole and the second conducive layer being formed on the first conductive layer;
a thin film dielectric layer formed on the lower electrode layer; and
an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

8. The capacitor with the hole structure according to claim 7, further comprising an insulating layer interposed between the lower electrode layer and the inner wall of the trench-hole.

9. The capacitor with the hole structure according to claim 7, wherein the dielectric layer is made of one or more high dielectric materials selected from titanium oxide group, or a material having dopant added therein.

10. The capacitor with the hole structure according to claim 9, wherein the first conductive layer and the fourth conductive layer are made of one metal material of Cu, Ag, Au, Al, Ir, Ni, Co, Mo, and W, or a conductive oxide or a conductive nitride thereof, and
the second conductive layer and the third conductive layer are made of Ru material, or conductive polysilicon material having dopant added therein.

11. A manufacturing method of a capacitor with a hole structure, comprising:
preparing a substrate having a plurality of through-holes formed therein;
forming, on an inner wall of the through-hole, a lower electrode layer including a first conductive layer having a low specific resistance and a second conductive layer having a specific resistance higher than that of the first conductive layer, the first conductive layer being formed on the inner wall of the through-hole and the second conducive layer being formed on the first conductive layer;
forming a thin film dielectric layer formed on the lower electrode layer; and
forming, on the thin film dielectric layer, an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

12. The manufacturing method of the capacitor with the hole structure according to claim 11, wherein the forming of the lower electrode layer further includes forming an adhesive seed layer on the inner wall of the through-hole, and the first conductive layer is formed on the adhesive seed layer.

13. The manufacturing method of the capacitor with the hole structure according to claim 11, wherein the preparing of the substrate further includes forming an insulating layer on the inner wall of the through-hole and a surface of the substrate, and the lower electrode layer is formed on the insulating layer formed on the inner wall.

14. The manufacturing method of the capacitor with the hole structure according to claim 11, wherein the dielectric layer is made of one or more high dielectric materials selected from titanium oxide group, or a material having dopant added therein.

15. The manufacturing method of the capacitor with the hole structure according to claim 11, wherein the lower electrode layer and the upper electrode layer are formed by any one of ALD, CVD, PECVD, PVD, sputtering, and plating processes.

16. The manufacturing method of the capacitor with the hole structure according to claim 15, wherein the first conductive layer and the fourth conductive layer are made of one metal material of Cu, Ag, Au, Al, Ir, Ni, Co, Mo, and W, or a conductive oxide or a conductive nitride thereof, and
the second conductive layer and the third conductive layer are made of Ru material, or conductive polysilicon material having dopant added therein.

17. A manufacturing method of a capacitor with a hole structure, comprising:
preparing a substrate having a plurality of trench-holes formed therein;
forming, on an inner wall of the trench-hole, a lower electrode layer including a first conductive layer having a low specific resistance and a second conductive layer having a specific resistance higher than that of the first conductive layer, the first conductive layer being formed on the inner wall of the trench-hole and the second conducive layer being formed on the first conductive layer;
forming a thin film dielectric layer formed on the lower electrode layer; and
forming, on the thin film dielectric layer, an upper electrode layer including a third conductive layer and a fourth conductive layer having a specific resistance lower than that of the third conductive layer, the third conductive layer being formed on the thin film dielectric layer and the fourth conductive layer being formed on the third conductive layer.

18. The manufacturing method of the capacitor with the hole structure according to claim 17, wherein the dielectric layer is made of one or more high dielectric materials selected from titanium oxide group, or a material having dopant added therein.

19. The manufacturing method of the capacitor with the hole structure according to claim 17, wherein the lower electrode layer and the upper electrode layer are formed by any one of ALD, CVD, PECVD, PVD, sputtering, and plating processes.

20. The manufacturing method of the capacitor with the hole structure according to claim 19, wherein the first conductive layer and the fourth conductive layer are made of one metal material of Cu, Ag, Au, Al, Ir, Ni, Co, Mo, and W, or a conductive oxide or a conductive nitride thereof, and
the second conductive layer and the third conductive layer are made of Ru material, or conductive polysilicon material having dopant added therein.
